(19) United States
(12) Patent Application Publication
(10) Pub. No.: US 2026/0029717 A1
(43) Pub. Date: Jan. 29, 2026

(54) PITCH SPLITTING FOR EUV IMAGING

(71) Applicant: Tokyo Electron Limited, Tokyo (JP)

(72) Inventors: Michael Murphy, Albany, NY (US); Jodi Grzeskowiak, Albany, NY (US); Charlotte Cutler, Albany, NY (US); David Conklin, Saratoga Springs, NY (US)

(21) Appl. No.: 18/784,631

(22) Filed: Jul. 25, 2024

(51) Int. Cl. G03F 7/11; G03F 7/00; G03F 7/004; G03F 7/16

(52) U.S. Cl. CPC G03F 7/11; G03F 7/0048; G03F 7/161; G03F 7/168; G03F 7/70033; G03F 7/70583

(57) ABSTRACT

A method of patterning a substrate includes forming a mandrel over the substrate, the mandrel including an extreme ultraviolet (EUV) resist, and depositing a first overcoat layer over the mandrel from a first solution, the first solution including a first solvent, a first polymer, and an agent generator or an acid. The method further includes selectively removing the first overcoat layer leaving a first mandrel portion surrounded by a second mandrel portion, the second mandrel portion being formed by modifying an outer portion of the mandrel by the first overcoat layer. The method further includes depositing a second overcoat layer over the second mandrel portion from a second solution, the second overcoat layer being separated from the first mandrel portion by the second mandrel portion, the second solution including a second solvent, and a second polymer. And the method further includes forming a second mandrel along a sidewall of the first mandrel portion by selectively removing the second mandrel portion relative to the first mandrel portion.

### TECHNICAL FIELD

This disclosure relates generally to semiconductor fabrication, and, in particular embodiments, to pitch splitting for extreme ultraviolet (EUV) imaging.

### BACKGROUND

Semiconductor devices typically are fabricated by sequentially depositing insulating or dielectric layers, conductive layers, and other layers of material over a semiconductor substrate, and patterning the layers using lithography to form circuit components and elements on the substrate. The semiconductor industry continues to increase the density of electronic components (e.g., transistors, diodes, resistors, capacitors, etc.) by continual reductions in minimum feature size, allowing more components to be integrated into a particular area.

### SUMMARY

In accordance with an embodiment of this disclosure, a method of patterning a substrate includes forming a mandrel over the substrate, the mandrel including an extreme ultraviolet (EUV) resist, and depositing a first overcoat layer over the mandrel from a first solution, the first solution including a first solvent, a first polymer, and an agent generator or an acid, the first polymer including a first constitutional unit. The method further includes selectively removing the first overcoat layer leaving a first mandrel portion surrounded by a second mandrel portion, the second mandrel portion being formed by modifying an outer portion of the mandrel by the first overcoat layer. The method further includes depositing a second overcoat layer over the second mandrel portion from a second solution, the second overcoat layer being separated from the first mandrel portion by the second mandrel portion, the second solution including a second solvent, and a second polymer, the second polymer including a second constitutional unit and a third constitutional unit. And the method further includes forming a second mandrel along a sidewall of the first mandrel portion by selectively removing the second mandrel portion relative to the first mandrel portion.

In accordance with another embodiment of this disclosure, a method of patterning a substrate includes forming a mandrel over the substrate, the mandrel including an extreme ultraviolet (EUV) resist, and coating a first solution to form a first overcoat layer over the mandrel, the first solution including a first solvent, a first polymer, and a thermal acid generator (TAG), the first polymer including a first constitutional unit. The method further includes baking the substrate to cause the thermal acid generator to generate a solubility-changing agent, the baking causing the solubility-changing agent to diffuse into the mandrel to form a first mandrel portion and a second mandrel portion with different solubility than the mandrel, and rinsing the substrate with a developer solution to remove the first overcoat layer leaving the first mandrel portion surrounded by the second mandrel portion. The method further includes coating a second solution to form a second overcoat layer over the second mandrel portion, the second overcoat layer being separated from the first mandrel portion by the second mandrel portion, the second solution including a second solvent, a second polymer, and a cage organic compound, the second polymer including a second constitutional unit and a third constitutional unit. And the method further includes forming a second mandrel along a sidewall of the first mandrel portion by selectively removing the second mandrel portion relative to the first mandrel portion.

And in accordance with yet another embodiment of this disclosure, a method of patterning a substrate includes providing the substrate including a mandrel, the mandrel including an extreme ultraviolet (EUV) resist, and coating the substrate with a first solution to form a first overcoat layer over the mandrel, the first solution including a first organic solvent, a first polymer, and an agent generator or an acid, the first polymer including a first constitutional unit. The method further includes selectively removing the first overcoat layer leaving a first mandrel portion surrounded by a second mandrel portion, the second mandrel portion being formed by modifying an outer portion of the mandrel by the first overcoat layer, and coating the substrate with a second solution to form a second overcoat layer over the second mandrel portion, the second overcoat layer being separated from the first mandrel portion by the second mandrel portion, the second solution including a second organic solvent and a second polymer including a second constitutional unit, a third constitutional unit, and a fourth constitutional unit. And the method further includes forming a second mandrel along a sidewall of the first mandrel portion by selectively removing the second mandrel portion relative to the first mandrel portion.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1G illustrate cross-sectional views of an example semiconductor workpiece during an example patterning process, according to certain embodiments;

FIG. 2 illustrates a block diagram of an example lithography system, according to certain embodiments;

FIG. 3 illustrates an example liquid-based spin-on deposition system, according to certain embodiments;

FIG. 4 illustrates an example method for patterning a semiconductor workpiece, according to certain embodiments; and

FIG. 5 illustrates an example method for patterning a semiconductor workpiece, according to certain embodiments.

### DETAILED DESCRIPTION OF ILLUSTRATIVE EMBODIMENTS

Generally, lithography tools are a prime example of technological innovation to meet next generation semiconductor requirements such as the shift from 193 nm immersion (193i) to extreme ultraviolet (EUV) to high-numerical aperture (NA) EUV. However, EUV lithography suffers certain drawbacks, including increasing costs, lower throughput, and the difficulty of identifying suitable polymers to form crosslinkable overcoat layers. While 193i lithography used a pitch-splitting process, the same materials cannot be used for EUV lithography because of the different absorption of the materials. For example, EUV resists may comprise phenol- and styrene-based polymers instead of the synthetically challenging polymers with aliphatic or bicyclic sidechains used in 193i lithography. However, changing the photoresist may render the 193i pitch-splitting process unsuitable for EUV processes, for example, by introducing a chemistry mismatch with trim layer and overcoat formulations. In particular, solvents such as isoamyl ether (IAE) which may be used for the overcoat layers in an EUV pitch-splitting process should neither mix with nor solubilize the EUV resist.

Another drawback for process flows that utilize EUV resist imaging is that the EUV-resist imaging step typically utilizes EUV resists with a phenolic functionality prohibited in 193i nodes due to high absorbance at that wavelength. Thus, alternative patterning formulations of overcoats for use with EUV resists (to enable smaller feature fabrication through pitch-splitting processes) would be advantageous.

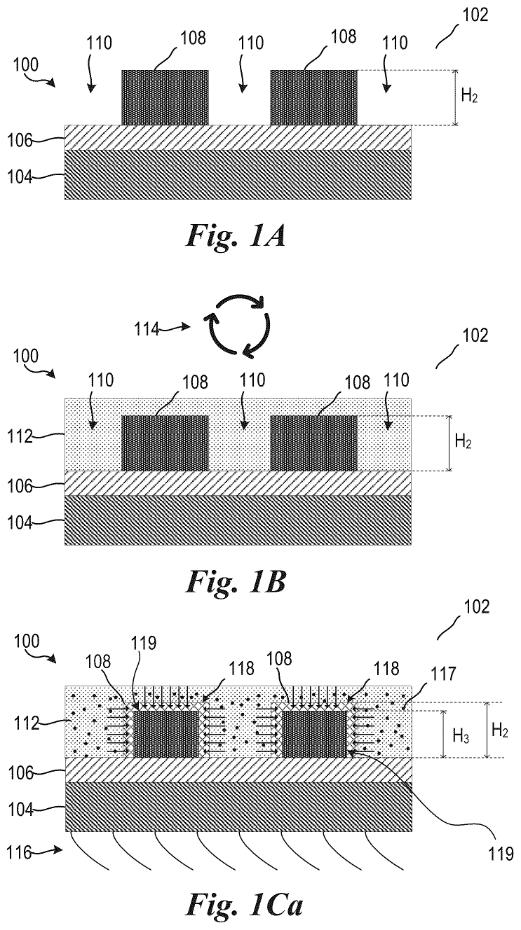

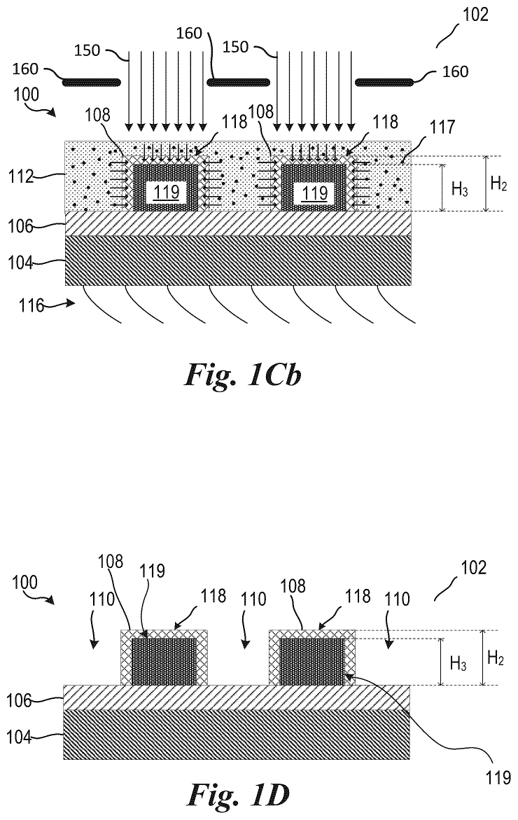

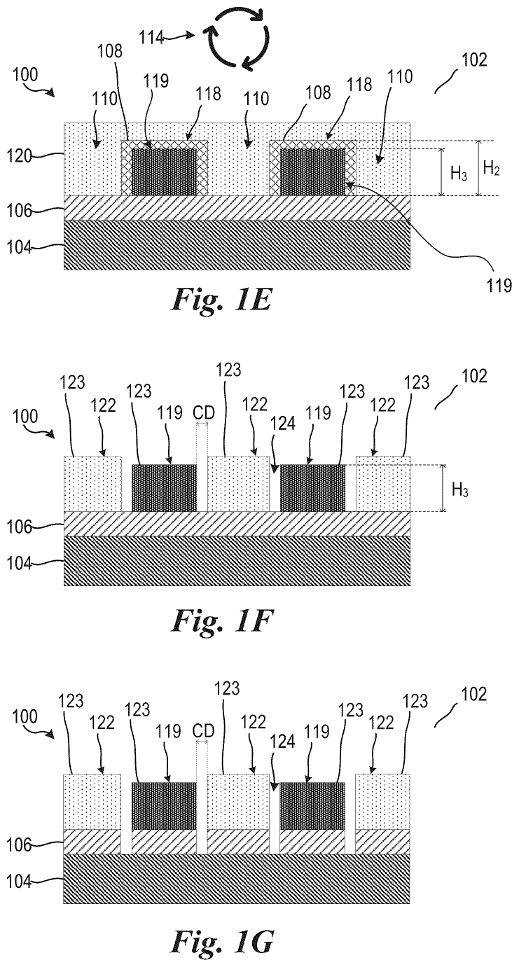

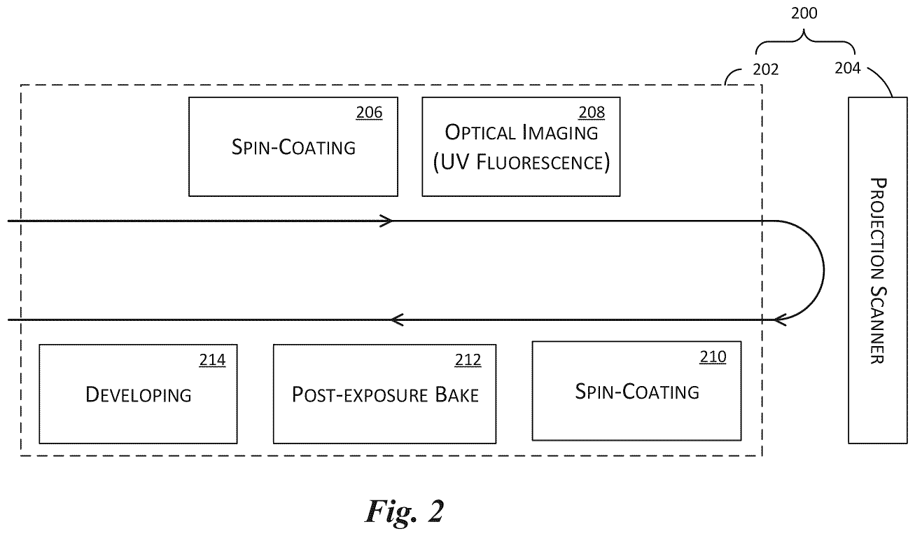

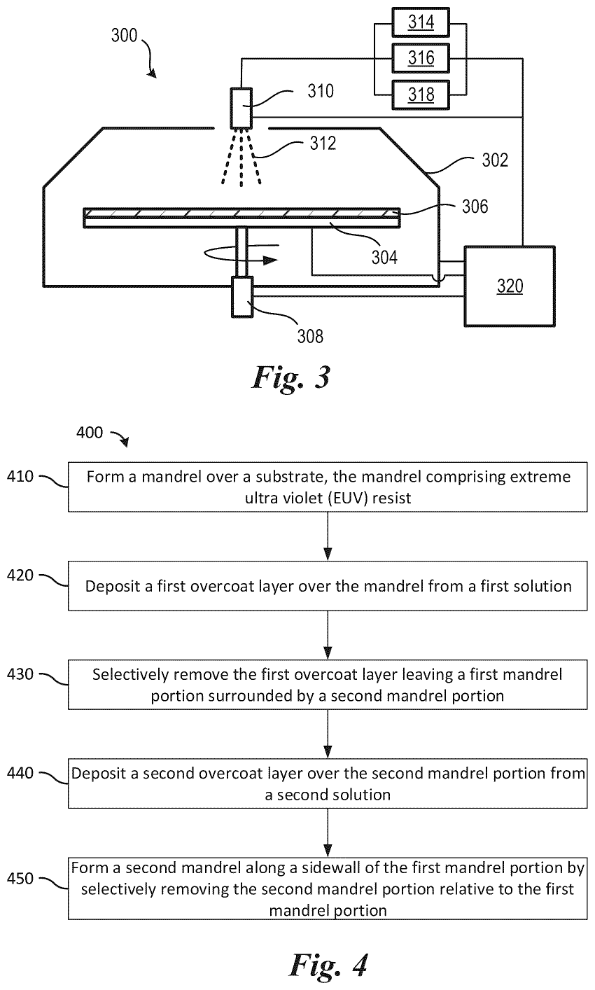

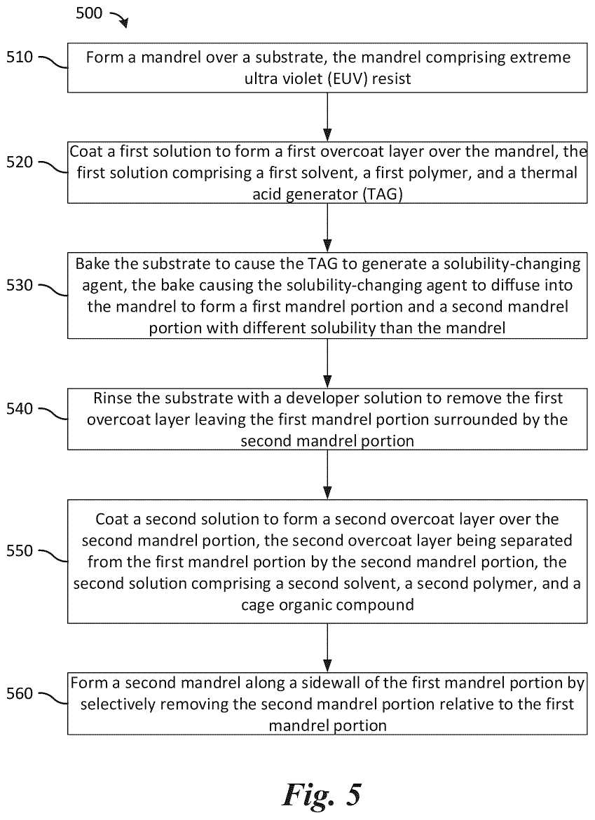

In various embodiments, this disclosure describes compositions for overcoat layers and methods for their use in EUV pitch-splitting process flows. The following description describes the various embodiments. FIGS. 1A-1G illustrate intermediate steps of an example acid-in process flow (specifically, a pitch-splitting process) comprising an EUV-resist imaging step and the FIGS. 1A-1G are used to described material considerations to enable the EUV-resist imaging step. FIG. 2 is used to illustrate an EUV lithography system capable of being used in the pitch-splitting process described using FIGS. 1A-1G. An example liquid-based spin-on deposition system capable of depositing materials for the EUV-resist imaging is illustrated in FIG. 3. And further example methods of pitch-splitting processes comprising an EUV-resist imaging step are described using FIGS. 4-5.

FIGS. 1A-1G illustrate cross-sectional views of an example semiconductor workpiece 100 during an example patterning process 102, according to certain embodiments. For example, the patterning process 102 may be an acid-in process flow which may be implemented on an EUV resist, and comprises an EUV resist imaging (lithography) step. In certain embodiments, some or all of patterning process 102 may be referred to as an anti-spacer patterning process, or simply as an anti-spacer process. In certain embodiments, patterning process 102 may be used to achieve sub-resolution features in an underlying layer of a semiconductor wafer. Sub-resolution features may refer to features that are smaller than can be achieved directly according to a wavelength of the lithography technology being used (e.g., without the use of some additional patterning process, such as an anti-spacer process).

Semiconductor workpiece 100 generically refers to any suitable semiconductor element being processed in accordance with embodiments of this disclosure. Semiconductor workpiece 100, or portions thereof, also may be referred to as a semiconductor wafer, such as a silicon wafer. Semiconductor workpiece 100 includes a substrate 104, an intermediate layer 106 positioned on substrate 104, and mandrels 108 positioned on intermediate layer 106.

Substrate 104 may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate 104 is not limited to any particular base structure, underlying layer or overlying layer, patterned or un-patterned, but rather, may include any such layer or base structure, and any combination of layers and/or base structures. Substrate 104 may be a bulk substrate such as a bulk silicon wafer, a silicon-on-insulator (SOI) wafer, or various other semiconductor substrates.

Intermediate layer 106 and mandrels 108 may be a photolithography stack. Intermediate layer 106 also may be referred to as an underlying layer, particularly when described relative to mandrels 108 or the layer from which mandrels 108 are formed. This disclosure contemplates substrate 104 and intermediate layer 106 having any suitable thicknesses.

Intermediate layer 106 represents any suitable combination of one or more layers, one or more of which are to be patterned using mandrels 108. For example, intermediate layer 106 may include a hard mask layer, an amorphous carbon layer, a silicon carbide layer, a bottom anti-reflective coating, and/or any other layer, one or more of which may be useful for a patterning process. Additionally or alternatively, intermediate layer 106 may include a stack of films. For example, intermediate layer 106 may include films of dielectric and/or conductive materials, such as oxide, silicon oxide, silicon nitride, silicon oxynitride, silicon carbide, titanium nitride, tantalum nitride, their alloys, and combinations thereof. For example, intermediate layer 106 can be a dielectric layer or alternating dielectric layers.

Semiconductor workpiece 100 may be formed in any suitable manner, including using any suitable combination of wet and/or dry deposition and etch techniques. For example, semiconductor workpiece 100 may be deposited using any technique appropriate for the material to be deposited and the semiconductor feature being formed. Suitable deposition processes may include a spin-on coating process, a chemical vapor deposition (CVD) process, an atomic layer deposition (ALD) process, plasma deposition processes (e.g., a plasma-enhanced CVD (PECVD) process), and/or other layer deposition processes or combinations of processes.

Mandrels 108 may be formed of extreme ultraviolet (EUV) resist and may be lines or other suitable types of semiconductor structures. In various embodiments, mandrels 108 are formed of EUV resist, such as metal-containing resists comprising metals such as tin incorporated into an organic polymer matrix or as part of small molecular compounds; metal oxide resists such as those including tin, hafnium, zirconium; chemically-amplified resists (CARs); and others comprising an acid diffused in a metal oxide resist (mOR). Furthermore, mandrels 108 may be formed using EUV lithographic technology.

Mandrels 108 may be formed from a layer of EUV resist material. To form mandrels 108, an EUV resist layer may be processed in two primary stages to create a pattern for further processing underlying layers (e.g., intermediate layer 106): an exposure stage and a development stage. During the exposure stage, the EUV resist material reacts to extreme ultraviolet light to form a pattern on the EUV resist material according to a pattern mask. For example, due to exposure to the EUV light, portions of the EUV resist that are exposed to the EUV light may have different material properties than non-exposed regions of the EUV resist. The different material properties may be volatility, reactivity, and/or solubility. For example, depending on the type of EUV resist material used, portions of the EUV resist exposed to EUV light may become more or less soluble in a developer solution, such that those exposed regions may become more difficult or less difficult, respectively, to remove when processed using the developer solution. These changes correspond, respectively, to positive- or negative-tone development. In a positive-tone embodiment, during the development stage, the EUV resist material is exposed to a developer solution to remove portions of the EUV resist layer.

Mandrels 108 may have any suitable thickness, referred to throughout this disclosure as height (labeled as H₂). In certain embodiments, mandrels 108 have a thickness of 5 nm to 100 nm, for example 10 nm to 30 nm. It should be understood that these thickness values are provided as examples only, and that mandrels 108 may have any suitable thickness.

Recesses 110 may be defined by mandrels 108. Although two mandrels 108 are shown, additional mandrels 108 may be formed laterally from the illustrated mandrels 108. Recesses 110 may have any suitable lateral dimension. Although this disclosure primarily describes “recesses,” other suitable features might be formed in or on a semiconductor substrate, including (whether or not considered “recesses”) lines, holes, trenches, vias, and/or other suitable structures, using embodiments of this disclosure.

As described in greater detail below following FIG. 1G, the patterning process used to form mandrels 108 shown in FIG. 1A is implemented according to the material considerations described in this disclosure, which may result in a height (H₂) of mandrels 108 being reduced prior to performing subsequent steps of patterning process 102, but enables acid-in process flows on semiconductor wafers comprising EUV resist.

To create features having smaller critical dimension than those of mandrels 108, additional processing may be performed. In this particular example, an anti-spacer patterning process may be performed on the semiconductor workpiece 100 of FIG. 1A.

As shown in FIG. 1B, a first overcoat layer 112 may be deposited on semiconductor workpiece 100 through the use of a first solution. The first solution comprises a first solvent between about 95-99 wt %, a first polymer between about 1.0-5.0 wt %, and an agent generator or an acid between about 0.1-2.0 wt %. In various embodiments, the first solvent may be IAE, or any other suitable solvent (such as isobutyl isobutyrate (IBIB)) or solvent blend with similar properties and which does not mix with or solubilize the EUV resist. For example, alternative solvents or solvent blends may be similar to IAE or IBIB in Hansen solubility parameter space, with a Hansen distance (Rₐ) from IAE or IBIB of 5 or less. The first polymer may be any material comprising a first constitutional unit that has hydrophobic functionality, the first polymer being acid non-reactive, and soluble in the first solvent. For example, the first polymer may be Poly n-butyl methacrylate or T-Butyl methacrylate copolymers having lower polarity and hydrophyllicity. For example, the first constitutional unit may be n-butyl, or t-butyl, or whichever constitutional unit of the first polymer is hydrophobic or is responsible for the hydrophobic functionality of the first polymer. In an embodiment where the third component of the first solution is an agent generator, the agent generator may be a photoacid generator (PAG) or a thermal acid generator (TAG), where PAGs generate an agent (e.g., acid) through exposure to actinic radiation and TAGs generate an agent (e.g., acid) through heat exposure (a bake process). Example PAGs which may be used as the agent generator are N-camphorsulfonyloxynaphthalimide, and other PAGs comprising a triphenyl sulphonium (TPC) cation and a medium strength acid (such as paratoluene sulfonic acid). Example TAGs which may be used as the agent generator are either ionic or non-ionic in nature with the same acid considerations as PAG but with a cation comprising a quaternary ammonium salt or other groups capable of facilitating the release of the acid in a functional temperature range below 140° C. In an embodiment where the third component of the first solution is an acid, any suitable acid may be used.

First overcoat layer 112 may fill recesses 110 and cover mandrels 108. First overcoat layer 112 may be a multicomponent material that, as deposited, comprises the materials of the first solution described above. In comparison to conventional process flows, the first overcoat layer 112 of this disclosure does not specify the first component be soluble in TMAH.

First overcoat layer 112 may be deposited on semiconductor workpiece 100 in any suitable manner. For example, first overcoat layer 112 may be deposited by spin-coating, spray-coating, dip-coating, or roll-coating. As a particular example, first overcoat layer 112 may be deposited on semiconductor workpiece 100 using a spin-on deposition technique 114, which also may be referred to as spin-coating.

With spin-on deposition, a particular material (e.g., the first solution described above) is deposited on a substrate (e.g., on intermediate layer 106 formed on substrate 104). The substrate is then rotated (if not already rotating, possibly at a relatively low velocity) at a relatively high velocity so that centrifugal force causes deposited material to move toward edges of the substrate, thereby coating the substrate. Excess material is typically spun off the substrate. In certain embodiments, spin-on deposition technique 114 includes dispensing liquid chemicals onto semiconductor workpiece 100 (e.g., on a top surface of intermediate layer 106 and over exposed surfaces of mandrels 108) using a coating module with a liquid delivery system that may dispense one or more types of liquid chemicals. The dispense volume can be between 0.2 mL to 10 mL, for example 0.5 mL to 2 mL. The substrate (e.g., workpiece 100) may be secured to a rotating chuck that supports the substrate. The rotating speed during liquid dispense can be between 50 rpm to 3000 rpm, for example 1000 rpm to 2000 rpm. The system may also include an anneal module that may bake or apply light radiation to the substrate after the chemicals have been dispensed. It should be understood that this example spin-on deposition technique 114 and associated values are provided as examples only. Further, the rotating speed may be specific to wafer dimensions and percentage of solids of solutions.

Additionally or alternatively, first overcoat layer 112 may be deposited using a chemical vapor deposition (CVD), plasma-enhanced CVD (PECVD), atomic layer deposition (ALD), or other suitable process.

In certain embodiments, first overcoat layer 112 may be deposited in a deposition module (e.g., a spin-coating module) of a larger track system for an EUV lithography process. An example lithography system that includes a track system is described in greater detail below with reference to FIG. 2.

FIGS. 1Ca-1Cb illustrate various embodiments in which the first overcoat layer 112 comprises agent generators (such as PAG, or TAG) or an acid. FIG. 1Ca illustrates an embodiment where the first solution used to form the first overcoat layer 112 comprises a TAG, or an acid. FIG. 1Cb illustrates an embodiment where the first solution used to form the first overcoat layer 112 comprises a PAG.

FIG. 1Ca may be used to illustrate an embodiment where the agent generator is a TAG, or to illustrate an embodiment where the first overcoat layer 112 comprises an acid. In an embodiment where the first overcoat layer 112 comprises a TAG as an agent-generating ingredient, a bake process 116 on the semiconductor workpiece 100 may cause the TAG to generate an acid as the solubility-changing agent 117 and may cause the solubility-changing agent 117 to diffuse into a portion of mandrels 108 (represented by the arrows directed into the mandrels 108) through a separate bake process (or, in some embodiments, the same bake process) on the semiconductor workpiece 100. The diffusion of the solubility-changing agent 117 into a portion of mandrels 108 may be used to cause those portions of mandrels 108 to become soluble in a developer and form second mandrel portions 118.

FIG. 1Ca may also illustrate an alternative embodiment where the first overcoat layer 112 comprises an acid ingredient as the solubility-changing agent 117. In that embodiment, a bake process 116 on the semiconductor workpiece 100 may cause the solubility-changing agent 117 to diffuse into a portion of mandrels 108 to cause those portions of mandrels 108 to become soluble in a developer and form second mandrel portions 118.

As shown in FIG. 1Cb, a photomask 160 may be used such that specified regions of the first overcoat layer 112 are exposed to a plurality of light rays 150, where the plurality of light rays 150 may be actinic radiation. Illuminating semiconductor workpiece 100 using the plurality of light rays 150 through the photomask 160 may cause an agent-generating ingredient (such as a PAG) to generate solubility-changing agent 117 (e.g., acid) and the bake process 116 may be used to diffuse solubility-changing agent 117 into a portion of mandrels 108 and to cause those portions of mandrels 108 to become soluble in a developer and form second mandrel portions 118. In other embodiments, the first overcoat layer 112 may be exposed to the plurality of light rays 150 without the photomask 160.

For example, in the case first overcoat layer 112 comprises a PAG as an agent-generating ingredient, illuminating semiconductor workpiece 100 may cause the PAG to generate an acid as the solubility-changing agent 117 and the solubility-changing agent 117 may diffuse into a portion of mandrels 108 (represented by the arrows directed into the mandrels 108) through a bake process 116 on the semiconductor workpiece 100 to cause those portions of mandrels 108 to become soluble in a developer and form second mandrel portions 118.

Baking semiconductor workpieces 100 using the bake process 116 illustrated in either of FIG. 1Ca or 1Cb generally causes solubility-changing agent 117 (regardless of whether the solubility-changing agent 117 was generated by an acid, or an agent generator) to diffuse into a perimeter region of mandrels 108 to a target depth, and to modify that perimeter region to be soluble in a developer, forming second mandrel portions 118. For example, the modified mandrel portions (second mandrel portions 118) may form a deprotected shell-like structure around remaining portions of mandrels 108 (or unmodified portions, such as first mandrel portion 119), consuming a portion of an outer perimeter of mandrels 108 and thereby reducing both a vertical and lateral dimension of mandrels 108. Among other factors, baking time and/or temperature may be optimized to control a depth of diffusion of the solubility-changing agent to achieve the target depth. The target depth, particularly on sidewall surfaces of mandrels 108, may generally correspond to the target critical dimension of recesses in a structure being formed using process 102, as described further below in connection with FIG. 1G.

In certain embodiments, first mandrel portions 119 of mandrels 108 have a reduced height, shown as H₃, relative to the height H₂ of mandrels 108 in FIG. 1A, and a difference between H₂ and H₃ represents a depth of diffusion of the solubility-changing agent, at least in a vertical dimension. In certain embodiments, the depth of diffusion, and resulting change in solubility of mandrels 108, is approximately equal on all sides of mandrels 108.

In certain embodiments, baking semiconductor workpiece 100 may be performed by heating semiconductor workpiece 100 in a process chamber at a temperature between 50° C. to 250° C., for example between 60° C. to 140° C. in certain embodiments, in vacuum or under a gas flow. In a particular example, semiconductor workpiece 100 is baked for 1 to 3 minutes. The bake conditions may be selected to promote the diffusion of solubility-changing agent within and out of first overcoat layer 112 into mandrels 108, causing a change in solubility of a perimeter of mandrels 108 to the target depth. This disclosure contemplates executing the bake in any suitable manner which does not deform the profile of mandrels 108. Typically, acid diffusion temperatures may be between 70° C. to 100° C. and may be performed for less than 1 min (for example, 20 s to 30 s).

As illustrated in FIG. 1D, first overcoat layer 112 may be removed selectively from semiconductor workpiece 100, with minimal to no removal of second mandrel portions 118 of mandrels 108. This disclosure contemplates selectively removing first overcoat layer 112 in any suitable manner. In certain embodiments, first overcoat layer 112 may be removed selectively from semiconductor workpiece 100 using a suitable solvent or other developer, which may include the solvent used to formulate first overcoat layer 112, such as IAE, IBIB, or another solvent or solvent blend with a Hansen distance (Rₐ) from IAE or IBIB of 5 or less.

As illustrated in FIG. 1E, a second overcoat layer 120 may be deposited on semiconductor workpiece 100 through the use of a second solution. The second solution comprises a second solvent between about 95-99 wt %, a second polymer between about 1.0-4.5 wt % comprising an etch-resistance modifying monomer between about 0.1-2.0 wt %. In various embodiments, the second solvent may be the same as the first solvent, or IAE, or any other suitable solvent (such as IBIB) or solvent blend with similar properties and which does not mix with or solubilize the EUV resist. For example, alternative solvents or solvent blends may be similar to IAE or IBIB in Hansen solubility parameter space, with a Hansen distance (Rₐ) from IAE or IBIB of 5 or less. The etch-resistance modifying monomer may impart an ohnishi parameter to the second overcoat layer 120 to be similar to the EUV resist. The second polymer comprises a second constitutional unit with hydrophobic functionality and a third constitutional unit with hydrophilic functionality, the second polymer being soluble in the second solvent. For example, the second constitutional unit may be t-butyl or n-butyl. For example, the third constitutional unit may be methacrylic acid or another acid with a functionality of similar hydrophyllicity. In various embodiments, the etch-resistance modifying monomer may be any suitable material to modify the etch rate of the material of the second overcoat layer 120. For example, in an embodiment where the etch-resistance modifying monomer is instead an etch-resistance modifying compound, the material of the etch-resistance modifying compound may be a bulky compound such as a cage organic compound or a compound comprising aromatic functionality. In various embodiments, the material of the etch-resistance modifying monomer may be styrene, hydroxystyrene, hydroxyadamantyl methacrylate, or multiring structures.

In similar embodiments where the second solution comprises the second solvent, the second polymer comprising the etch-resistance modifying monomer, the second constitutional unit may be 50-70% of the second polymer and the third constitutional unit may be 30-50% of the second polymer.

In other embodiments, the second solution comprises a second solvent between about 95-99 wt % and a second polymer between about 1.0-4.5 wt %, without a separate etch-resistance modifying compound. The second solvent may be the same as described above. In these embodiments, the second polymer comprises a second constitutional unit with hydrophobic functionality, a third constitutional unit with hydrophilic functionality, and a fourth constitutional unit conferring etch resistance, such as by comprising bulky cage or aromatic functionality. Similarly, the second polymer is soluble in the second solvent. For example, the second constitutional unit may be the same as above. The third constitutional unit may be the same as above. The fourth constitutional unit may be an etch-resistance modifying monomer, such as styrene, hydroxystyrene, hydroxyadamantyl methacrylate, or multiring structures.

In similar embodiments where the second solution comprises the second solvent and the second polymer without a separate etch-resistance modifying compound, the second constitutional unit may be 50-70% of the second polymer, the third constitutional unit may be 30-50% of the second polymer, and the fourth constitutional unit may be 4-10% of the second polymer. In other embodiments, the first constitutional unit may comprise both hydrophobic functionality and aromatic functionality to modify the etch-resistance of the second overcoat layer 120 such that the second polymer comprises the second constitutional unit and the third constitutional unit without the fourth constitutional unit.

Second overcoat layer 120 may fill recesses 110 and cover mandrels 108, including over second mandrel portions 118 of mandrels 108. Second overcoat layer 120 may be a multicomponent material that, as deposited, comprises the materials of the second solution described above. In contrast to the first overcoat layer 112, the process flow may specify the second overcoat layer 120 is soluble in aqueous TMAH with a low etch rate (Rₘᵢₙ), such as Rₘᵢₙ between about 0.1-0.5 nm/second. Alternative process steps using different etchants in aqueous solvent may be contemplated as well.

Second overcoat layer 120 may include a polymer that is capable of filling recesses 110. The material of second overcoat layer 120 may have a low dissolution rate in a chosen developer for revealing recesses 124, as described in greater detail below with reference to FIG. 1E. The material of second overcoat layer 120 also may be able to resist etching at a later stage to transfer a pattern into intermediate layer 106 (e.g., the pattern as defined in part by patterned structures 123, which include remaining portions of second overcoat layer 120, and recesses 124, and associated patterned transfer to be described in greater detail below with reference to FIGS. 1F-1G). In all embodiments, the material of second overcoat layer 120 (e.g., a polymer) and formulation additives are soluble in one or more solvents that will have little to no intermixing with the underlying EUV resist mandrel (e.g., mandrels 108).

Further, the material of second overcoat layer 120 and formulation additives may comprise copolymerization to match etch resistance properties with the mandrels 108 using a cage or aromatic functionality. Additionally, the material of second overcoat layer 120 and formulation additives comprise dissolution specifications in TMAH in order to remove the overburden and reveal the recess to form trenches without deteriorating the line formed by the second overcoat layer 120 formulation. In various embodiments, the material of second overcoat layer 120 and formulation additives may comprise copolymers that have both hydrophobic functionality like an alkyl methacrylate or alkyl styrene in conjunction with a hydrophilic moiety such as methacrylic acid, or diHFA (dihydroxyfluoro alcohol).

The molecular weight of materials of the second overcoat layer 120 may be formulated to enable solubility in the aqueous base. High-molecular weight materials may be less soluble and may also have a sufficiently large radius of gyration as to compromise the resolution with which the material of the second overcoat layer 120 may be deposited, leading to unacceptable surface roughness. Such polymer compositions may be the same polymer compositions described above as components of the second solution used to deposit the second overcoat layer 120. Although second overcoat layer 120 is described as including particular materials, this disclosure contemplates second overcoat layer 120 including any suitable materials.

In yet another embodiment, second overcoat layer 120 may be replaced with a leaving group that allows coating in a hydrophobic solvent and dissolution in hydrophyllic. For example, this could be a TAG or PAG activated ester functionality leaving group.

Second overcoat layer 120 may be deposited on semiconductor workpiece 100 in any suitable manner. For example, second overcoat layer 120 may be deposited by spin-coating, spray-coating, dip-coating, or roll-coating. As a particular example, second overcoat layer 120 may be deposited on semiconductor workpiece 100 using a spin-on deposition technique 114, in a similar manner to that described above with reference to FIG. 1B.

In certain embodiments, second overcoat layer 120 may be deposited in a deposition module (e.g., a spin-coating module) of a larger track system for an EUV lithography process. An example EUV lithography system that includes a track system is described in greater detail below with reference to FIG. 2.

As illustrated in FIG. 1F, second mandrel portions 118 of mandrels 108 and portions of second overcoat layer 120 may be removed selectively to reveal first mandrel portions 119 of mandrels 108 and second mandrels 122 of second overcoat layer 120. This disclosure contemplates removing second mandrel portions 118 of mandrels 108 and portions of second overcoat layer 120 in any suitable manner, such as with aqueous TMAH.

In certain embodiments, the portions of second overcoat layer 120 and second mandrel portions 118 of mandrels 108 are removed selectively using a developer. For example, the developer may remove a sufficient portion of second overcoat layer 120 to reveal second mandrel portions 118 of mandrels 108, and then remove those second mandrel portions 118 of mandrels 108 at a more rapid removal rate (e.g., dissolution rate). As a particular example, the developer may remove at a first removal rate a sufficient portion of second overcoat layer 120 to reveal second mandrel portions 118 of mandrels 108, and then remove second mandrel portions 118 of mandrels 108 at a greater second removal rate. In certain embodiments, the second removal rate is significantly larger than the first removal rate (1000:1, as a non-limiting example) such that once second mandrel portions 118 of mandrels 108 are revealed, second mandrel portions 118 of mandrels 108 are removed much more rapidly than additional removal of portions of second overcoat layer 120.

Removal of second mandrel portions 118 of mandrels 108 forms patterned structures 123 formed from unmodified portions of mandrels 108 (from the first mandrel portions 119). Removal of second mandrel portions 118 of mandrels 108 reveals recesses 124 defined by second mandrels 122 of second overcoat layer 120 and patterned structures 123.

In the state illustrated in FIG. 1F, the combination of second mandrels 122 of second overcoat layer 120, patterned structures 123, and recesses 124 define a pattern that can be transferred to an underlying layer (e.g., intermediate layer 106). A difference between a width of a recess 124 (the critical dimension, or CD) and the adjacent structures (e.g., a second mandrel 122 of second overcoat layer 120 and a patterned structure 123) defines an aspect ratio. As described above, in general, a larger aspect ratio creates difficulties as recesses 124 are formed or when a patterned defined by the recesses 124 and adjacent structures is transferred to an underlying layer. These difficulties may lead to pattern collapse, surface roughness, lack of fidelity to a target critical dimension, and/or other difficulties. Thus, minimizing an aspect ratio defined by second mandrels 122 of second overcoat layer 120, patterned structures 123, and recesses 124 may be desirable.

Certain embodiments of this disclosure provide techniques for forming semiconductor workpiece 100 at the state illustrated in FIG. 1A. Thus, in certain embodiments, techniques described herein may be incorporated into a larger patterning process (e.g., process 102) for forming sub-resolution features. This disclosure provides example processes for reducing a height of structures patterned from EUV resist (e.g., mandrels 108) to a height H₂ as part of forming semiconductor workpiece 100 at the state illustrated in FIG. 1A. That is, the patterning process used to form mandrels 108 shown in FIG. 1A is implemented according to the concepts described in this disclosure, which results in a height (H₂) of mandrels 108 being reduced prior to performing subsequent steps of patterning process 102. Performing a height reduction at this stage may reduce an aspect ratio of a pattern defined using further steps of process 102 to produce recesses 124. Furthermore, the height reduction of structures patterned from EUV resist (e.g., mandrels 108) may be accomplished with little to no impact on an ability to accurately pattern structures from EUV resist (e.g., mandrels 108).

As shown in FIG. 1F, patterned structures 123 have a reduced height H₃ that is less than a height (H₂) of mandrels 108 (see FIG. 1A) and less than a height (H₁) of an EUV resist layer from which semiconductor structures were formed (not shown). This reduced height H₃ may be due at least in part to the manner in which semiconductor workpiece 100 is formed at the state illustrated in FIG. 1A. Recesses 124 have a lateral width, which may be referred to as the critical dimension (labeled as CD). This critical dimension (lateral width of recesses 124) may be the target critical dimension of process 102. In certain embodiments, the reduced height H₃ provides an improved ability to achieve the desired critical dimension of recesses 124.

Although heights of patterned structures 123 are shown to vary (e.g., heights of second mandrels 122 of second overcoat layer 120 are shown to be greater than heights of first mandrel portions 119 of mandrels 108), this disclosure contemplates second mandrels 122 of second overcoat layer 120 and first mandrel portions 119 of mandrels 108 having the same or different heights. In certain embodiments, processing conditions and formulation chemistry may be tuned to planarize and/or minimize discrepancies in heights of second mandrels 122 of second overcoat layer 120 and heights of first mandrel portions 119 of mandrels 108.

As illustrated in FIG. 1G, the pattern defined by the combination of second mandrels 122 of second overcoat layer 120, patterned structures 123, and recesses 124 may be transferred to intermediate layer 106. This pattern transfer may be performed using any suitable combination of etch processes, including any suitable wet etch process and dry etch processes. For example, the etch process may include one or more of a liquid etch, a chemical wet etch, a chemical dry etch, a plasma etch, an atomic layer etch, or other suitable etch process. In the illustrated example, transferring the pattern defined by the combination of second mandrels 122 of second overcoat layer 120, patterned structures 123, and recesses 124 to intermediate layer 106 includes extending recesses 124 into intermediate layer 106. Due at least in part to the improved CD of recesses 124 and/or the reduced height H₃, certain embodiments improve pattern transferring fidelity in transferring the pattern to the underlying layer (e.g., intermediate layer 106).

As detailed above for the pitch-splitting process illustrated in FIGS. 1A-1G, this disclosure describes compositions for overcoat layers and methods for their use in a track-based pitch-splitting process for semiconductor wafers comprising EUV resist. By controlling the abundance of a set of constitutional units in a polymer or copolymer in a solution used to form overcoat layers over EUV resist, track-based pitch-splitting processes may be enabled in process flows comprising EUV lithography steps. The benefits of this approach include being able to form features of smaller critical dimensions using EUV lithography and optimized process flows for track-based pitch-splitting processes using EUV resist and EUV lithography (as a result of the ability to tune the solutions based on process-flow specifications).

In other embodiments, the compositions described above for overcoat layers deposited over EUV resist may be used in other acid-in fabrication processes to enable track-based pitch-splitting processes on semiconductor wafers comprising EUV resist. Example processing tools capable of implementing track-based pitch-splitting processes that use an overcoat over EUV resist are described below using FIGS. 2-3.

FIG. 2-3 illustrate example processing tools that may be used, along or in combination, to deposit or process material considerations described above for various embodiments of this disclosure to enable track-based pitch-splitting processes on semiconductor wafers comprising EUV resist.

FIG. 2 illustrates a block diagram of an example EUV lithography system 200, according to certain embodiments. EUV lithography system 200 is just one example of a lithography system that may be used with certain embodiments. In the illustrated example, EUV lithography system 200 includes a track system 202 and a projection scanner 204. In certain embodiments, EUV lithography system 200 is generally configured for performing patterning processes, such as patterning EUV resist in an acid-in track-splitting process as described above using FIGS. 1A-1G).

Scanner 204 may be configured to perform an exposure phase of an EUV photolithography process, such as the EUV resist imaging (lithography) described above. In certain embodiments, scanner 204 is a combination of an optical and mechanical system to scan an optical image of a pattern printed on a photomask onto the surface of a wafer (e.g., semiconductor workpiece 100) coated with EUV resist. After scanning the pattern once, scanner 204 may be operated to step to an adjacent location on the same wafer where the scan is repeated to form another copy of the pattern. In this manner, the EUV resist layer is exposed to multiple copies of the pattern arranged in a rectangular matrix on the surface of the wafer.

Track system 202 includes a series of process modules assembled to allow potentially sequential execution of processes for the lithography process prior to the exposure and after the exposure step performed by scanner 204. Track system 202 provides the material processes such as coating the wafer with EUV resist, baking the EUV resist, and developing the EUV resist after exposure. In the illustrated example, the process modules of track system 202 include a spin-coating module 206, a spin-coating module 210, a PEB module 212, and a developing module 214 for developing the exposed EUV resist. Spin-coating modules 206 and 210 include a spin-coater, an example of which is described below with reference to FIG. 3. EUV resist materials, agent-containing layer materials, overcoat materials, and solvents are connected from a liquid supply system to suitable processing modules (e.g., spin-coating modules 206 and 210, developing module 214, etc.) via pipelines, filters, valves, and pumps.

In addition to process modules, track system 202 includes an imaging module 208 and could also include an inspection and metrology (IM) module.

Imaging module 208 may be an optical imaging module used to identify defects prior to exposing the EUV resist to a radiation pattern in scanner 204. Wafers coated with EUV resist are received from spin-coating module 206 and imaged in imaging module 208 using an imaging system that includes light sources and cameras. The light sources are configured to illuminate the wafer, while the cameras create photographic images of the surfaces. In certain embodiments, the imaging system of imaging module 208 includes cameras to image the wafer from various directions (e.g., from the top (side coated with EUV resist), bottom (backside), and side (beveled edges)). The cameras may be coupled to a controller of the imaging system that acquires and transmits the images to an inspection device for image analysis. The inspection device may identify defects using, for example, a processor of the inspection device configured to execute instructions stored in an electronic memory of the inspection device to perform appropriate image analysis. A defective wafer may be reworked or scrapped, as appropriate.

An IM module may receive wafers after a EUV resist layer has been exposed to a pattern of actinic radiation in scanner 204, and the pattern has been transferred to the EUV resist in developing module 214, where the exposed EUV resist is developed to form a patterned EUV resist layer. The quality of the EUV resist pattern is evaluated by inspecting and measuring various images of the EUV resist pattern in the IM module. The IM module may include, for example, a scanning electron microscope (SEM) for measuring critical dimensions in the EUV resist pattern. Wafers may fail inspection because of patterning defects or if the measurements are not within specified limits. Failed wafers may be discarded, or, if possible, reworked by stripping the EUV resist and repeating the EUV resist patterning process.

EUV lithography system 200 may include a transfer system to move a wafer (e.g., a semiconductor workpiece) from module-to-module of track system 202, as well as from track system 202 to projection scanner 204 (which may be considered “off track”) and from projection scanner 204 back to track system 202.

FIG. 3 illustrates an example liquid-based spin-on deposition system 300, according to certain embodiments. For example, liquid-based spin-on deposition system 300 may be used to process any of the described semiconductor workpieces to deposit any of the EUV resist layers (such as the EUV resist), barrier layers, EUV resist formulas, overcoat films or other suitable materials described in this disclosure (such as the material considerations described above). In certain embodiments, spin-on deposition system 300 may be a semi-closed spin-on deposition system used for coating substrates (wafers) with a desired layer. The semi-closed configuration may allow fume control and minimize exhaust volume.

In the illustrated example, spin-on deposition system 300 includes a process chamber 302 that includes a substrate holder 304 for supporting, heating, and rotating (spinning) a substrate 306 (which may include any of the semiconductor workpieces described in this disclosure at appropriate stages of processing), a rotating apparatus 308 (e.g., a motor), and a liquid delivery nozzle 310 configured for providing a processing liquid 312 to an upper surface of the substrate 306. Liquid supply systems 314, 316, and 318 supply different processing liquids to the liquid delivery nozzle 310. For depositing a EUV resist, the different processing liquids can include, for example, a first reactant in a first liquid, a second reactant in a second liquid, and a rinsing liquid. For depositing an overcoat layer, the different processing liquids may comprise, for example, a first liquid, a second liquid, and a third liquid to comprise a solution comprising the polymers at the weight ratios described above for the first overcoat layer 112 or the second overcoat layer 120. For depositing a first overcoat layer 112 or the second overcoat layer 120 described above, the different processing liquids may comprise, for example, a first liquid comprising a first solution to deposit the first overcoat layer 112, a second liquid comprising a second solution to deposit the second overcoat layer 120, and a rinsing liquid. In certain embodiments, spin-on deposition system 300 includes additional liquid delivery nozzles for providing different liquids to substrate 306. Example rotating speeds can be between about 500 rpm and about 1500 rpm, for example 1000 rpm, during exposure of an upper surface of substrate 306 to processing liquid 312.

Spin-on deposition system 300 may include a controller 320 that can be coupled to and control process chamber 302; liquid supply systems 314, 316, and 318; liquid delivery nozzle 310; rotating apparatus 308, mechanism for heating substrate holder 304. Substrate 306 may be under an inert atmosphere during film deposition. Spin-on deposition system 300 may be configured to process substrates 306 of any suitable size.

FIGS. 4-5 illustrate example methods of patterning a substrate to enable pitch-splitting processes on EUV resist in accordance with embodiments of this disclosure. The methods of FIGS. 4-5 may be combined with other methods and performed using the systems and apparatuses as described herein, such as the tools illustrated in FIGS. 2-3, and the method illustrated by the processing steps of FIGS. 1A-1G. Although shown in a logical order, the arrangement and numbering of the steps of FIGS. 4-5 are not intended to be limited. The method steps of FIGS. 4-5 may be performed in any suitable order.

Referring to FIG. 4, step 410 of a method 400 of processing a substrate to enable pitch splitting on EUV resist forms a mandrel over the substrate, the mandrel comprising extreme ultraviolet (EUV) resist. The forming of the mandrel may be performed by any of the processes described above for depositing and patterning an EUV resist over a substrate. Step 420 deposits a first overcoat layer over the mandrel from a first solution. The first solution may be the first solution used to deposit the first overcoat layer 112 described above and illustrated in FIG. 1B.

Still referring to FIG. 4, step 430 of the method 400 selectively removes the first overcoat layer leaving a first mandrel portion surrounded by a second mandrel portion. For example, step 430 may be illustrated by FIGS. 1Ca-1Cb and FIG. 1D. Any suitable process may be used to form the first mandrel portion and the second mandrel portion, such as using a bake to cause an agent generating material of the first overcoat layer (in an embodiment where the agent generator is a TAG) to be generated and then diffuse into the mandrel to change the solubility characteristics in the outer perimeter of the mandrel (thus, forming the second mandrel portion with a different solubility than the first mandrel portion).

Step 440 of the method 400 deposits a second overcoat layer over the second mandrel portion from a second solution. For example, the second solution may be the second solution described above for depositing the second overcoat layer 120 of FIG. 1E. Further, step 450 of the method 400 forms a second mandrel along a sidewall of the first mandrel portion by selectively removing the second mandrel portion relative to the first mandrel portion. For example, step 450 may remove the second mandrel portion to form the second mandrel by exposing the upper surface of the substrate to a developer solution, such as described for FIG. 1F. Further steps may be performed after step 450 in order to transfer the pattern formed by the first mandrel portion and the second mandrel to an underlayer of the substrate, such as described using FIG. 1G.

Now referring to FIG. 5, step 510 of a method 500 of processing a substrate to enable pitch splitting on EUV resist forms a mandrel over the substrate, the mandrel comprising extreme ultraviolet (EUV) resist. The forming of the mandrel may be performed by any of the processes described above for depositing and patterning an EUV resist over a substrate. For example, the EUV resist may be deposited using the spin-coater 300 illustrated in FIG. 3, and patterned using the EUV lithography system 200 of FIG. 2. Step 520 coats a first solution to form a first overcoat layer over the mandrel, the first solution comprising a first solvent, a first polymer, and a TAG. Alternative embodiments may use an acid or a PAG in place of the TAG with slight modifications (adding an exposure step for the PAG to generate a solubility-changing agent). The first solution may comprise the materials described above for the first solution used to form the first overcoat layer 112 of FIG. 1B. The coat of first solution to form the first overcoat layer may be performed by the spin-coater 300 of FIG. 3 in an embodiment.

Still referring to FIG. 5, step 530 bakes the substrate to cause the TAG to generate a solubility-changing agent (such as solubility-changing agent 117 illustrated in FIGS. 1Ca-1Cb). The bake causing the solubility-changing agent to diffuse into the mandrel to form a first mandrel portion and a second mandrel portion with different solubility than the mandrel (and the first mandrel portion). Step 540 of the method 500 rinses the substrate with a developer solution (such as the developer solution described above in the description of FIG. 1D) to remove the first overcoat layer leaving the first mandrel portion surrounded by the second mandrel portion.

After, step 550 coats a second solution to form a second overcoat layer over the second mandrel portion, the second overcoat layer being separated from the first mandrel portion by the second mandrel portion, the second solution comprising a second solvent, a second polymer, and a cage organic compound. All components of the second solution may be as described above for the second solution used to form the second overcoat layer 120 of FIG. 1E. Step 560 forms a second mandrel along a sidewall of the first mandrel portion by selectively removing the second mandrel portion relative to the first mandrel portion. For example, step 560 may remove the second mandrel portion to form the second mandrel by exposing the upper surface of the substrate to a developer solution, such as described for FIG. 1F. Further steps may be performed after step 560 in order to transfer the pattern formed by the first mandrel portion and the second mandrel to an underlayer of the substrate, such as described using FIG. 1G.

Although the embodiments described above are for track-based pitch-splitting processes, the material considerations for overcoat layers deposited over EUV resist may be applied to other embodiments also comprising acid-in processing flows with an overcoat layer deposited over EUV resist.

Example embodiments of the invention are described below. Other embodiments can also be understood from the entirety of the specification as well as the claims filed herein.

Example 1. A method of patterning a substrate includes forming a mandrel over the substrate, the mandrel including an extreme ultraviolet (EUV) resist, and depositing a first overcoat layer over the mandrel from a first solution, the first solution including a first solvent, a first polymer, and an agent generator or an acid, the first polymer including a first constitutional unit. The method further includes selectively removing the first overcoat layer leaving a first mandrel portion surrounded by a second mandrel portion, the second mandrel portion being formed by modifying an outer portion of the mandrel by the first overcoat layer. The method further includes depositing a second overcoat layer over the second mandrel portion from a second solution, the second overcoat layer being separated from the first mandrel portion by the second mandrel portion, the second solution including a second solvent, and a second polymer, the second polymer including a second constitutional unit and a third constitutional unit. And the method further includes forming a second mandrel along a sidewall of the first mandrel portion by selectively removing the second mandrel portion relative to the first mandrel portion.

Example 2. The method of example 1, where the second polymer includes an etch-resistance modifying monomer.

Example 3. The method of one of examples 1 or 2, where the second solution includes a cage organic compound or aromatic compound.

Example 4. The method of one of examples 1 to 3, where the second constitutional unit includes a hydrophobic functionality and an aromatic functionality, and where the third constitutional unit includes a hydrophilic functionality.

Example 5. The method of one of examples 1 to 4, where the first solvent is between 95-99 wt % in the first solution, the first polymer is between 1.0-5.0 wt % in the first solution, the agent generator or the acid is between 0.1-2.0 wt % in the first solution, the second solvent is between 95-99 wt % in the second solution, and the second polymer is between 1-4.5 wt % in the second solution.

Example 6. The method of one of examples 1 to 5, where the second constitutional unit includes 50-70% of the second polymer and the third constitutional unit includes 30-50% of the second polymer.

Example 7. The method of one of examples 1 to 6, where the first solvent and the second solvent include isoamyl ether (IAE).

Example 8. The method of one of examples 1 to 7, where the first solvent and the second solvent are separated in Hansen solubility parameter space by a distance Rₐ of 5 or less.

Example 9. The method of one of examples 1 to 8, where the first constitutional unit and the second constitutional unit include hydrophobic functionality, and the third constitutional unit includes hydrophilic functionality.

Example 10. The method of one of examples 1 to 9, where the first solution includes the agent generator, and where the agent generator includes a photoacid generator (PAG).

Example 11. The method of one of examples 1 to 10, where the first solvent includes isoamyl ether (IAE) or isobutyl isobutyrate (IBIB), the first polymer includes poly n-butyl methacrylate or t-butyl methacrylate, the first constitutional unit includes n-butyl or t-butyl, the PAG includes N-camphorsulfonyloxynaphthalimide, the second solvent includes isoamyl ether (IAE) or isobutyl isobutyrate (IBIB), the second polymer includes poly n-butyl methacrylate or t-butyl methacrylate, the second constitutional unit includes n-butyl or t-butyl, and the third constitutional unit includes methacrylic acid.

Example 12. The method of one of examples 1 to 11, where the first solution includes the agent generator, and where the agent generator includes a thermal acid generator (TAG).

Example 13. The method of one of examples 1 to 12, where the first solvent includes isoamyl ether (IAE) or isobutyl isobutyrate (IBIB), the first polymer includes poly n-butyl methacrylate or t-butyl methacrylate, the first constitutional unit includes n-butyl or t-butyl, the second solvent includes isoamyl ether (IAE) or isobutyl isobutyrate (IBIB), the second polymer includes poly n-butyl methacrylate or t-butyl methacrylate, the second constitutional unit includes n-butyl or t-butyl, and the third constitutional unit includes methacrylic acid.

Example 14. The method of one of examples 1 to 13, where the first solution includes the acid, and where the acid includes paratoluene sulfonic acid.

Example 15. The method of one of examples 1 to 14, where the second overcoat layer includes a dissolution rate (Rₘᵢₙ) between 0.1-0.5 nm/second in tetramethylammonium hydroxide (TMAH).

Example 16. The method of one of examples 1 to 15, further including etching the second overcoat layer to expose the second mandrel portion before forming the second mandrel.

Example 17. The method of one of examples 1 to 16, further including etching a pattern formed by the first mandrel portion and the second mandrel into an underlayer of the substrate.

Example 18. A method of patterning a substrate includes forming a mandrel over the substrate, the mandrel including an extreme ultraviolet (EUV) resist, and coating a first solution to form a first overcoat layer over the mandrel, the first solution including a first solvent, a first polymer, and a thermal acid generator (TAG), the first polymer including a first constitutional unit. The method further includes baking the substrate to cause the thermal acid generator to generate a solubility-changing agent, the baking causing the solubility-changing agent to diffuse into the mandrel to form a first mandrel portion and a second mandrel portion with different solubility than the mandrel, and rinsing the substrate with a developer solution to remove the first overcoat layer leaving the first mandrel portion surrounded by the second mandrel portion. The method further includes coating a second solution to form a second overcoat layer over the second mandrel portion, the second overcoat layer being separated from the first mandrel portion by the second mandrel portion, the second solution including a second solvent, a second polymer, and a cage organic compound, the second polymer including a second constitutional unit and a third constitutional unit. And the method further includes forming a second mandrel along a sidewall of the first mandrel portion by selectively removing the second mandrel portion relative to the first mandrel portion.

Example 19. The method of example 18, where the first overcoat layer is insoluble with the mandrel before the baking.

Example 20. The method of one of examples 18 or 19, where the second solvent and the first solvent include isoamyl ether (IAE).

Example 21. The method of one of examples 18 to 20, where the first solvent includes isoamyl ether (IAE) or isobutyl isobutyrate (IBIB), the first polymer includes poly n-butyl methacrylate or t-butyl methacrylate, the first constitutional unit includes n-butyl or t-butyl, the second solvent includes isoamyl ether (IAE) or isobutyl isobutyrate (IBIB), the second polymer includes poly n-butyl methacrylate or t-butyl methacrylate, the second constitutional unit includes n-butyl or t-butyl, and the third constitutional unit includes methacrylic acid.

Example 22. The method of one of examples 18 to 21, where the first solvent and the second solvent are separated in Hansen solubility parameter space by a distance Rₐ of 5 or less.

Example 23. The method of one of examples 18 to 22, where the first solvent is between 95-99 wt % in the first solution, the first polymer is between 1.0-5.0 wt % in the first solution, and the TAG is between 0.1-2.0 wt % in the first solution, and where the second solvent is between 95-99 wt % in the second solution, the second polymer is between 1.0-4.5 wt % in the second solution, and the cage organic compound is between 0.1-2.0 wt % in the second solution.

Example 24. The method of one of examples 18 to 23, where the second constitutional unit includes 50-70% of the second polymer and the third constitutional unit includes 30-50% of the second polymer.

Example 25. A method of patterning a substrate includes providing the substrate including a mandrel, the mandrel including an extreme ultraviolet (EUV) resist, and coating the substrate with a first solution to form a first overcoat layer over the mandrel, the first solution including a first organic solvent, a first polymer, and an agent generator or an acid, the first polymer including a first constitutional unit. The method further includes selectively removing the first overcoat layer leaving a first mandrel portion surrounded by a second mandrel portion, the second mandrel portion being formed by modifying an outer portion of the mandrel by the first overcoat layer, and coating the substrate with a second solution to form a second overcoat layer over the second mandrel portion, the second overcoat layer being separated from the first mandrel portion by the second mandrel portion, the second solution including a second organic solvent and a second polymer including a second constitutional unit, a third constitutional unit, and a fourth constitutional unit. And the method further includes forming a second mandrel along a sidewall of the first mandrel portion by selectively removing the second mandrel portion relative to the first mandrel portion.

Example 26. The method of example 25, where the first overcoat layer is insoluble with the mandrel before selectively removing the first overcoat layer.

Example 27. The method of one of examples 25 or 26, where the first organic solvent and the second organic solvent include isoamyl ether (IAE).

Example 28. The method of one of examples 25 to 27, where the first organic solvent and the second organic solvent are separated in Hansen solubility parameter space by a distance Rₐ of 5 or less.

Example 29. The method of one of examples 25 to 28, where the first organic solvent is between 95-99 wt % in the first solution, the first polymer is between 1.0-5.0 wt % in the first solution, and the agent generator or the acid is between 0.1-2.0 wt % in the first solution, and where the second organic solvent is between 95-99 wt % in the second solution, and the second polymer is between 1.0-4.5 wt % in the second solution.

Example 30. The method of one of examples 25 to 29, where the second constitutional unit includes 50-70% of the second polymer, the third constitutional unit includes 30-50% of the second polymer, and the fourth constitutional unit includes 4-10% of the second polymer.

Example 31. The method of one of examples 25 to 30, where the first constitutional unit and the second constitutional unit include hydrophobic functionality, the third constitutional unit includes hydrophilic functionality, and the fourth constitutional unit includes etch-resistance modifying functionality.

Example 32. The method of one of examples 25 to 31, where the first organic solvent includes isoamyl ether (IAE) or isobutyl isobutyrate (IBIB), the first polymer includes poly n-butyl methacrylate or t-butyl methacrylate, the first constitutional unit includes n-butyl or t-butyl, the agent generator or acid includes a photoacid generator (PAG), the second organic solvent includes isoamyl ether (IAE) or isobutyl isobutyrate (IBIB), the second polymer includes poly n-butyl methacrylate or t-butyl methacrylate, the second constitutional unit includes n-butyl or t-butyl, the third constitutional unit includes methacrylic acid, and the fourth constitutional unit includes styrene, hydroxystyrene, hydroxyadamantyl methacrylate, or multiring structures.

Example 33. The method of one of examples 25 to 32, where selectively removing the first overcoat layer includes baking the substrate and rinsing the substrate with a developer solution.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of patterning a substrate, the method comprising:
forming a mandrel over the substrate, the mandrel comprising an extreme ultraviolet (EUV) resist;
depositing a first overcoat layer over the mandrel from a first solution, the first solution comprising a first solvent, a first polymer, and an agent generator or an acid, the first polymer comprising a first constitutional unit;
selectively removing the first overcoat layer leaving a first mandrel portion surrounded by a second mandrel portion, the second mandrel portion being formed by modifying an outer portion of the mandrel by the first overcoat layer;
depositing a second overcoat layer over the second mandrel portion from a second solution, the second overcoat layer being separated from the first mandrel portion by the second mandrel portion, the second solution comprising a second solvent, and a second polymer, the second polymer comprising a second constitutional unit and a third constitutional unit; and
forming a second mandrel along a sidewall of the first mandrel portion by selectively removing the second mandrel portion relative to the first mandrel portion.

2. The method of claim 1, wherein the second solution comprises a cage organic compound or aromatic compound.

3. The method of claim 1, wherein the second constitutional unit comprises a hydrophobic functionality and an aromatic functionality, and wherein the third constitutional unit comprises a hydrophilic functionality.

4. The method of claim 1, wherein the first solvent is between 95-99 wt % in the first solution, the first polymer is between 1.0-5.0 wt % in the first solution, the agent generator or the acid is between 0.1-2.0 wt % in the first solution, the second solvent is between 95-99 wt % in the second solution, and the second polymer is between 1-4.5 wt % in the second solution.

5. The method of claim 1, wherein the second constitutional unit comprises 50-70% of the second polymer and the third constitutional unit comprises 30-50% of the second polymer.

6. The method of claim 1, wherein the first solvent and the second solvent are separated in Hansen solubility parameter space by a distance Rₐ of 5 or less.

7. The method of claim 1, wherein the first constitutional unit and the second constitutional unit comprise hydrophobic functionality, and the third constitutional unit comprises hydrophilic functionality.

8. The method of claim 1, wherein the first solution comprises the agent generator, and wherein the agent generator comprises a photoacid generator (PAG).

9. The method of claim 8, wherein the first solvent comprises isoamyl ether (IAE) or isobutyl isobutyrate (IBIB), the first polymer comprises poly n-butyl methacrylate or t-butyl methacrylate, the first constitutional unit comprises n-butyl or t-butyl, the PAG comprises N-camphorsulfonyloxynaphthalimide, the second solvent comprises isoamyl ether (IAE) or isobutyl isobutyrate (IBIB), the second polymer comprises poly n-butyl methacrylate or t-butyl methacrylate, the second constitutional unit comprises n-butyl or t-butyl, and the third constitutional unit comprises methacrylic acid.

10. The method of claim 1, wherein the first solution comprises the acid, and wherein the acid comprises paratoluene sulfonic acid.

11. The method of claim 1, wherein the second overcoat layer comprises a dissolution rate (Rₘᵢₙ) between 0.1-0.5 nm/second in tetramethylammonium hydroxide (TMAH).

12. The method of claim 1, further comprising:
etching the second overcoat layer to expose the second mandrel portion before forming the second mandrel; and
etching a pattern formed by the first mandrel portion and the second mandrel into an underlayer of the substrate.

13. A method of patterning a substrate, the method comprising:
forming a mandrel over the substrate, the mandrel comprising an extreme ultraviolet (EUV) resist;
coating a first solution to form a first overcoat layer over the mandrel, the first solution comprising a first solvent, a first polymer, and a thermal acid generator (TAG), the first polymer comprising a first constitutional unit;
baking the substrate to cause the thermal acid generator to generate a solubility-changing agent, the baking causing the solubility-changing agent to diffuse into the mandrel to form a first mandrel portion and a second mandrel portion with different solubility than the mandrel;
rinsing the substrate with a developer solution to remove the first overcoat layer leaving the first mandrel portion surrounded by the second mandrel portion;
coating a second solution to form a second overcoat layer over the second mandrel portion, the second overcoat layer being separated from the first mandrel portion by the second mandrel portion, the second solution comprising a second solvent, a second polymer, and a cage organic compound, the second polymer comprising a second constitutional unit and a third constitutional unit; and
forming a second mandrel along a sidewall of the first mandrel portion by selectively removing the second mandrel portion relative to the first mandrel portion.

14. The method of claim 13, wherein the first overcoat layer is insoluble with the mandrel before the baking, and the first solvent and the second solvent are separated in Hansen solubility parameter space by a distance Rₐ of 5 or less.

15. The method of claim 13, wherein the first solvent comprises isoamyl ether (IAE) or isobutyl isobutyrate (IBIB), the first polymer comprises poly n-butyl methacrylate or t-butyl methacrylate, the first constitutional unit comprises n-butyl or t-butyl, the second solvent comprises isoamyl ether (IAE) or isobutyl isobutyrate (IBIB), the second polymer comprises poly n-butyl methacrylate or t-butyl methacrylate, the second constitutional unit comprises n-butyl or t-butyl, and the third constitutional unit comprises methacrylic acid.

16. The method of claim 13, wherein the first solvent is between 95-99 wt % in the first solution, the first polymer is between 1.0-5.0 wt % in the first solution, and the TAG is between 0.1-2.0 wt % in the first solution, and wherein the second solvent is between 95-99 wt % in the second solution, the second polymer is between 1.0-4.5 wt % in the second solution, and the cage organic compound is between 0.1-2.0 wt % in the second solution.

17. A method of patterning a substrate, the method comprising:
providing the substrate comprising a mandrel, the mandrel comprising an extreme ultraviolet (EUV) resist;
coating the substrate with a first solution to form a first overcoat layer over the mandrel, the first solution comprising a first organic solvent, a first polymer, and an agent generator or an acid, the first polymer comprising a first constitutional unit;
selectively removing the first overcoat layer leaving a first mandrel portion surrounded by a second mandrel portion, the second mandrel portion being formed by modifying an outer portion of the mandrel by the first overcoat layer;
coating the substrate with a second solution to form a second overcoat layer over the second mandrel portion, the second overcoat layer being separated from the first mandrel portion by the second mandrel portion, the second solution comprising a second organic solvent and a second polymer comprising a second constitutional unit, a third constitutional unit, and a fourth constitutional unit; and
forming a second mandrel along a sidewall of the first mandrel portion by selectively removing the second mandrel portion relative to the first mandrel portion.

18. The method of claim 17, wherein the first overcoat layer is insoluble with the mandrel before selectively removing the first overcoat layer, and the first organic solvent and the second organic solvent are separated in Hansen solubility parameter space by a distance Rₐ of 5 or less.

19. The method of claim 17, wherein:
the first constitutional unit and the second constitutional unit comprise hydrophobic functionality, the third constitutional unit comprises hydrophilic functionality, and the fourth constitutional unit comprises etch-resistance modifying functionality; and
the second constitutional unit comprises 50-70% of the second polymer, the third constitutional unit comprises 30-50% of the second polymer, and the fourth constitutional unit comprises 4-10% of the second polymer.

20. The method of claim 19, wherein the first organic solvent comprises isoamyl ether (IAE) or isobutyl isobutyrate (IBIB), the first polymer comprises poly n-butyl methacrylate or t-butyl methacrylate, the first constitutional unit comprises n-butyl or t-butyl, the agent generator or acid comprises a photoacid generator (PAG), the second organic solvent comprises isoamyl ether (IAE) or isobutyl isobutyrate (IBIB), the second polymer comprises poly n-butyl methacrylate or t-butyl methacrylate, the second constitutional unit comprises n-butyl or t-butyl, the third constitutional unit comprises methacrylic acid, and the fourth constitutional unit comprises styrene, hydroxystyrene, hydroxyadamantyl methacrylate, or multiring structures.
